(19) United States
(12) Patent Application Publication
(10) Pub. No.: US 2026/0101699 A1
(43) Pub. Date: Apr. 9, 2026

(54) TRAINING DEVICE, INFORMATION PROCESSING APPARATUS, SUBSTRATE PROCESSING APPARATUS, SUBSTRATE PROCESSING SYSTEM, TRAINING METHOD AND PROCESSING CONDITION DETERMINING METHOD

(71) Applicant: SCREEN HOLDINGS CO., LTD., Kyoto (JP)

(72) Inventors: Masahiro TOKUYAMA, Kyoto (JP); Kensuke SHINOHARA, Kyoto (JP); Sei NEGORO, Kyoto (JP)

(21) Appl. No.: 19/112,956

(22) PCT Filed: Aug. 28, 2023
(86) PCT No.: PCT/JP2023/030911

§ 371 Date: Mar. 18, 2025

(30) Foreign Application Priority Data
Sep. 26, 2022 (JP) 2022-153150

(51) Int. Cl. H10P 72/00

(52) U.S. Cl. CPC H10P 72/0424

(57) ABSTRACT

A training device includes an experimental data acquirer that acquires a first processing amount indicating a difference between a film thickness obtained before a process for a film and a film thickness obtained after the process for the film, after the process for the film is executed according to processing conditions including a variable condition indicating a relative position of a nozzle with respect to a substrate, with the relative position varying over time, a converter that converts the variable condition into compressed data and a model generator that generates a learning model, with the learning model executing machine learning using training data that includes the compressed data and the first processing amount corresponding to the processing conditions and predicting a second processing amount.

### TECHNICAL FIELD

The present invention relates to a training device, an information processing apparatus, a substrate processing apparatus, a substrate processing system, a training method and a processing condition determining method. In particular, the present invention relates to a training device that generates a learning model for simulating a process executed by a substrate processing apparatus according to processing conditions, an information processing apparatus that determines processing conditions using the learning model, a substrate processing apparatus including the information processing apparatus, a substrate processing system including the training device and the information processing apparatus, a training method executed by the training device, and a processing condition determining method executed by the information processing apparatus.

### BACKGROUND ART

In a semiconductor manufacturing process, there is a cleaning process. In the cleaning process, the film thickness of a film formed on a substrate is adjusted by an etching process of applying a chemical liquid to the substrate. In this film-thickness adjustment, it is important to execute the etching process such that the surface of the substrate is uniform, or to flatten the surface of the substrate by the etching process. In a case in which an etching liquid is discharged from a nozzle to a portion of the substrate, the nozzle is required to be moved in a radial direction with respect to the substrate. However, the etching process is a complicated process in which a processing amount indicating how much a film is processed changes due to differences in work for moving the nozzle. Further, the processing amount indicating how much the film is processed in the etching process is provided after the substrate is processed. Therefore, trial and error by an engineer are required to set the work for moving the nozzle. Determination for optimal nozzle work is costly and time consuming.

Patent Document 1 describes a device that determines scan speed information based on a target processing amount by using a trained model that has executed machine learning using training data in which “input” is a processing amount (etching amount) and “output” is the scan speed information. With this technique, one scan speed information set is determined based on the target processing amount.

[Patent Document 1] JP 2021-108367 A

### SUMMARY OF INVENTION

### Technical Problem

On the other hand, it is desired to more sufficiently complicate the work for moving a nozzle. The work for moving a nozzle is time-series data representing a position that changes over time. When the work for moving a nozzle is complicated, the sampling intervals are shortened, and thus the number of dimensions of the time-series data increases. In general, when the number of dimensions of training data increases, the number of data sets required for machine learning increases exponentially. Therefore, the number of dimensions of the training data increases, so that it is difficult to optimize a learning model obtained by machine learning. Further, because the etching process is a complicated process, the number of nozzle works suitable for a target processing amount is not limited to one, and the number of nozzle works may be two or more than two.

One object of the present invention is to provide a training device, a training method and a substrate processing system suitable for machine learning using a condition for a substrate process, with the condition changing over time.

Further, another object of the present invention is to provide an information processing apparatus, a substrate processing apparatus, a substrate processing system and a processing condition determining method that enable presentation of a plurality of processing conditions for a processing result of a complicated process of processing a substrate.

### Solution to Problem

A training device according to one aspect of the present invention includes an experimental data acquirer that acquires a first processing amount indicating a difference between a film thickness obtained before a process for a film and a film thickness obtained after the process for the film, after a substrate processing apparatus is driven according to processing conditions including a variable condition indicating a relative position of a nozzle with respect to a substrate and executes the process for the film formed on the substrate, with the relative position varying over time and with the substrate processing apparatus moving the nozzle for supplying a processing liquid to the substrate on which the film is formed and supplying the processing liquid to the substrate, a converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and a model generator that generates a learning model, with the learning model executing machine learning using training data that includes the compressed data and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus.

An information processing apparatus according to another aspect of the present invention that manages a substrate processing apparatus, wherein the substrate processing apparatus processes a film formed on a substrate by supplying a processing liquid to the substrate on which the film is formed, according to processing conditions including a variable condition indicating a relative position of a nozzle with respect to the substrate, with the relative position varying over time, includes a converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and a processing condition determiner that determines processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model is an inference model that has executed machine training using training data, with the training data including compressed data that is obtained when the variable condition included in processing conditions according to which the substrate processing apparatus has executed a process for the film formed on the substrate is converted by the converter, and a first processing amount indicating a difference between a film thickness obtained before the process for the film and a film thickness obtained after the process for the film in regard to the film formed on the substrate that has been processed by the substrate processing apparatus, and the processing condition determiner, in a case in which compressed data obtained when a temporary variable condition is converted by the converter is provided to the learning model and the second processing amount predicted by the learning model satisfies an allowable condition, determines processing conditions including the temporary variable condition as processing conditions for driving the substrate processing apparatus.

A substrate processing system according to yet another aspect of the present invention managing a substrate processing apparatus that processes a substrate, includes a training device and an information processing apparatus, wherein the substrate processing apparatus processes a film formed on a substrate by supplying a processing liquid to the substrate on which the film is formed, according to processing conditions including a variable condition indicating a relative position of a nozzle with respect to the substrate, with the relative position varying over time, the training device includes an experimental data acquirer that acquires a first processing amount indicating a difference between a film thickness obtained before a process for a film and a film thickness obtained after the process for the film, after the substrate processing apparatus is driven according to processing conditions and executes the process for the film formed on the substrate, a first converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to a substrate until a time when the substrate processing apparatus ends the nozzle work is divided into a number smaller than a data count of the variable condition, and a model generator that generates a learning model, with the learning model executing machine learning using training data that includes the compressed data obtained when the variable condition is converted by the first converter and the first processing amount corresponding to the processing conditions and predicting a second processing amount that indicates a difference between a film thickness obtained before a process for the film and a film thickness obtained after the process for the film in regard to the film formed on the substrate before being processed by the substrate processing apparatus, the information processing apparatus includes a second converter that is same as the first converter, and a processing condition determiner that determines processing conditions for driving the substrate processing apparatus using the learning model generated by the training device, and the processing condition determiner, in a case in which a conversion result obtained when a temporary variable condition is converted by the second converter is provided to the learning model and a second processing amount predicted by the learning model satisfies an allowable condition, determines processing conditions including the temporary variable condition as processing conditions for driving the substrate processing apparatus.

A training method according to yet another aspect of the present invention causes a computer to execute the processes of acquiring a first processing amount indicating a difference between a film thickness obtained before a process for a film and a film thickness obtained after the process for the film, after a substrate processing apparatus is driven according to processing conditions including a variable condition indicating a relative position of a nozzle with respect to a substrate and executes the process for the film formed on the substrate, with the relative position varying over time and with the substrate processing apparatus moving the nozzle for supplying a processing liquid to the substrate on which the film is formed and supplying the processing liquid to the substrate, converting the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and generating a learning model, with the learning model executing machine learning using training data that includes the compressed data and the first processing amount corresponding to the processing conditions and predicting a second processing amount that indicates a difference between a film thickness obtained before a process for the film and a film thickness obtained after the process for the film in regard to the film formed on the substrate before being processed by the substrate processing apparatus.

A processing condition determining method according to yet another aspect of the present invention executed by a computer that manages a substrate processing apparatus, wherein the substrate processing apparatus processes a film formed on a substrate by supplying a processing liquid to the substrate on which the film is formed, according to processing conditions including a variable condition indicating a relative position of a nozzle with respect to the substrate, with the relative position varying over time, the processing condition determining method includes a process of converting the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and a process of determining processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model is an inference model that has executed machine training using training data, with the training data including compressed data that is obtained when the variable condition included in processing conditions according to which the substrate processing apparatus has executed a process for the film formed on the substrate is converted in the process of converting, and a first processing amount indicating a difference between a film thickness obtained before the process for the film and a film thickness obtained after the process for the film in regard to the film formed on the substrate that has been processed by the substrate processing apparatus, and the process of determining processing conditions, in a case in which compressed data obtained when a temporary variable condition is converted in the process of converting is provided to the learning model and the second processing amount predicted by the learning model satisfies an allowable condition, includes determining processing conditions including the temporary variable condition as processing conditions for driving the substrate processing apparatus.

### Advantageous Effects of Invention

It is possible to provide a training device, a training method and a substrate processing system suitable for machine learning using a condition for a substrate process, with the condition changing over time.

Further, it is possible to provide an information processing apparatus, a substrate processing apparatus, a substrate processing system and a processing condition determining method that enable presentation of a plurality of processing conditions for a processing result of a complicated process of processing a substrate.

### BRIEF DESCRIPTION OF THE DRAWINGS

FIG. 1 is a diagram for explaining the configuration of a substrate processing system according to one embodiment of the present invention.

FIG. 2 is a diagram showing one example of the configuration of an information processing apparatus.

FIG. 3 is a diagram showing one example of the configuration of a training device.

FIG. 4 is a diagram showing one example of the functional configuration of a substrate processing system in one embodiment of the present invention.

FIG. 5 is a diagram for explaining a change in relative position of a nozzle with respect to a substrate.

FIG. 6 is a diagram showing one example of a nozzle work pattern.

FIG. 7 is a diagram showing one example of a film-thickness characteristic.

FIG. 8 is a diagram for explaining divided areas.

FIG. 9 is a diagram showing one example of compressed data.

FIG. 10 is a diagram for explaining a prediction device.

FIG. 11 is a flowchart showing one example of a flow of a prediction device generation process.

FIG. 12 is a flowchart showing one example of a flow of a processing condition determining process.

FIG. 13 is a flowchart showing one example of a flow of a compressed data generation process.

FIG. 14 is a flowchart showing one example of a flow of an additional training process.

FIG. 15 is a diagram showing one example of a processing liquid supply amount that changes over time.

FIG. 16 is a diagram showing another example of compressed data.

### DESCRIPTION OF EMBODIMENTS

A substrate processing system according to one embodiment of the present invention will be described below with reference to the drawings. In the following description, a substrate refers to a semiconductor substrate (semiconductor wafer), a substrate for an FPD (Flat Panel Display) such as a liquid crystal display device or an organic EL (Electro Luminescence) display device, a substrate for an optical disc, a substrate for a magnetic disc, a substrate for a magneto-optical disc, a substrate for a photomask, a ceramic substrate, a substrate for a solar battery, or the like.

### 1. Overall Configuration of Substrate Processing System

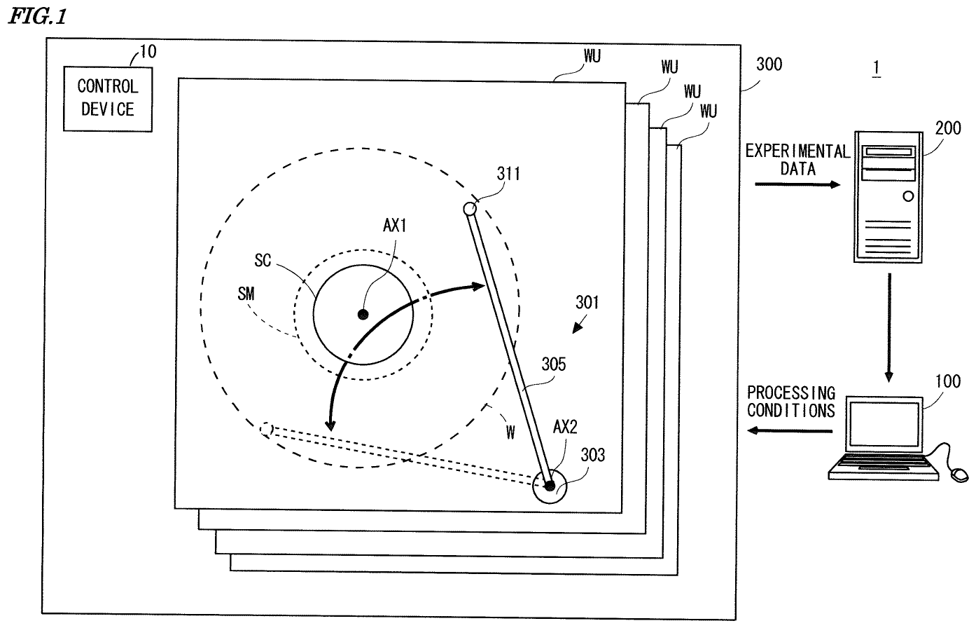

FIG. 1 is a diagram for explaining the configuration of the substrate processing system according to the one embodiment of the present invention. The substrate processing system 1 of FIG. 1 includes an information processing apparatus 100, a training device 200 and a substrate processing apparatus 300. The training device 200 is a server, for example, and the information processing apparatus 100 is a personal computer, for example.

The training device 200 and the information processing apparatus 100 are used to manage the substrate processing apparatus 300. The number of substrate processing apparatuses 300 managed by the training device 200 and the information processing apparatus 100 is not limited to one, and a plurality of substrate processing apparatuses 300 may be managed by the training device 200 and the information processing apparatus 100.

In the substrate processing system 1 according to the present embodiment, the information processing apparatus 100, the training device 200 and the substrate processing apparatus 300 are connected to one another by a wired communication line, a wireless communication line or a communication network. The information processing apparatus 100, the training device 200 and the substrate processing apparatus 300 are respectively connected to a network and can transmit and receive data to and from one another. As the network, a Local Area Network (LAN) or a Wide Area Network (WAN) is used, for example. Further, the network may be the Internet. Further, the information processing apparatus 100 and the substrate processing apparatus 300 may be connected to each other via a dedicated communication network. The connection state of the network may be wired or wireless.

The training device 200 is not necessarily required to be connected to the substrate processing apparatus 300 or the information processing apparatus 100 via a communication line or a communication network. In this case, the data generated in the substrate processing apparatus 300 may be transferred to the training device 200 via a recording medium. Further, the data generated in the training device 200 may be transferred to the information processing apparatus 100 via a recording medium.

In the substrate processing apparatus 300, a display device, a speech output device and an operation unit (not shown) are provided. The substrate processing apparatus 300 runs according to predetermined processing conditions (processing recipe) of the substrate processing apparatus 300.

### 2. Outline of Substrate Processing Apparatus

The substrate processing apparatus 300 includes a control device 10 and a plurality of substrate processing units WU. The control device 10 controls the plurality of substrate processing units WU. Each of the plurality of substrate processing units WU processes a substrate by supplying a processing liquid at a certain flow rate to the substrate W on which a film is formed. While the substrate W to be processed has the diameter of 300 mm in the present embodiment, the present invention is not limited to this. The processing liquid includes an etching liquid, and the substrate processing unit WU executes an etching process. The etching liquid is a chemical liquid. The etching liquid is a fluoronitric acid (a liquid mixture of hydrofluoric acid (HF) and nitric acid (HNO₃)), hydrofluoric acid, buffered hydrofluoric acid (BHF), ammonium fluoride, HFEG (a liquid mixture of hydrofluoric acid and ethylene glycol) or phosphoric acid (H₃PO₄), for example.

The substrate processing unit WU includes a spin chuck SC, a spin motor SM, a nozzle 311 and a nozzle moving mechanism 301. The spin chuck SC horizontally holds the substrate W. The substrate W is held by the spin chuck SC such that a first rotation axis AX1 of the spin motor SM coincides with the center of the substrate W. The spin motor SM has the first rotation axis AX1. The first rotation axis AX1 extends in an upward-and-downward direction. The spin chuck SC is attached to the upper end portion of the first rotation axis AX1 of the spin motor SM. When the spin motor SM rotates, the spin chuck SC rotates about the first rotation axis AX1. The spin motor SM is a stepping motor. The substrate W held by the spin chuck SC rotates about the first rotation axis AX1. Therefore, the rotation speed of the substrate W is the same as the rotation speed of the stepping motor. In a case in which an encoder that generates a rotation-speed signal indicating the rotation speed of the spin motor is provided, the rotation speed of the substrate W may be acquired from the rotation-speed signal generated by the encoder. In this case, a motor other than the stepping motor can be used as the spin motor SM.

The nozzle 311 supplies the etching liquid to the substrate W. The etching liquid is supplied from an etching liquid supplier (not shown) to the nozzle 311, and the nozzle 311 discharges the etching liquid to the rotating substrate W.

The nozzle moving mechanism 301 moves the nozzle 311 in a substantially horizontal direction. Specifically, the nozzle moving mechanism 301 has a nozzle motor 303 having a second rotation axis AX2 and a nozzle arm 305. The nozzle motor 303 is arranged such that the second rotation axis AX2 extends in a substantially vertical direction. The nozzle arm 305 has a longitudinal shape extending linearly. One end of the nozzle arm 305 is attached to the upper end of the second rotation axis AX2 such that the longitudinal direction of the nozzle arm 305 is different from the direction of the second rotation axis AX2. The nozzle 311 is attached to the other end of the nozzle arm 305 such that the discharge port of the nozzle 311 is directed downwardly.

When the nozzle motor 303 works, the nozzle arm 305 rotates about the second rotation axis AX2 in a horizontal plane. Thus, the nozzle 311 attached to the other end of the nozzle arm 305 moves (turns) in the horizontal direction about the second rotation axis AX2. The nozzle 311 discharges the etching liquid toward the substrate W while moving in the horizontal direction. The nozzle motor 303 is a stepping motor, for example.

The control device 10 includes a CPU (Central Processing Unit) and a memory, and controls the substrate processing apparatus 300 as a whole by execution by the CPU of a program stored in the memory. The control device 10 controls the spin motor SM and the nozzle motor 303.

The training device 200 receives experimental data from the substrate processing apparatus 300, causes a learning model to execute machine learning using the experimental data, and outputs the trained learning model to the information processing apparatus 100.

The information processing apparatus 100 determines processing conditions for processing a substrate to be processed by the substrate processing apparatus 300 using the trained learning model. The information processing apparatus 100 outputs the determined processing conditions to the substrate processing apparatus 300.

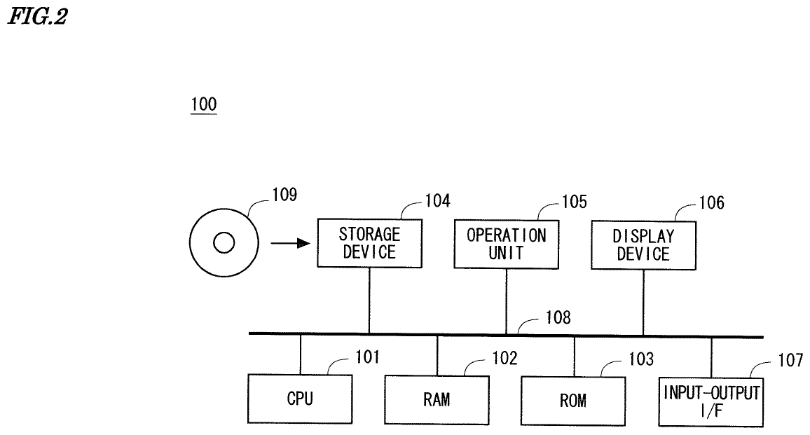

FIG. 2 is a diagram showing one example of the configuration of the information processing apparatus. With reference to FIG. 2, the information processing apparatus 100 includes a CPU 101, a RAM (Random Access Memory) 102, a ROM (Read Only Memory) 103, a storage device 104, an operation unit 105, a display device 106 and an input-output interface (I/F) 107. The CPU 101, the RAM 102, the ROM 103, the storage device 104, the operation unit 105, the display device 106 and the input-output I/F 107 are connected to a bus 108.

The RAM 102 is used as a work area for the CPU 101. A system program is stored in the ROM 103. The storage device 104 includes a storage medium such as a hard disc or a semiconductor memory and stores a program. The program may be stored in the ROM 103 or another external storage device.

A CD-ROM 109 is attachable to and detachable from the storage device 104. A recording medium storing a program to be executed by the CPU 101 is not limited to the CD-ROM 109. It may be an optical disc (MO (Magnetic Optical Disc)/MD (Mini Disc)/DVD (Digital Versatile Disc)), an IC card, an optical card, and a semiconductor memory such as a mask ROM or an EPROM (Erasable Programmable ROM). Further, the CPU 101 may download the program from a computer connected to the network and store the program in the storage device 104, or the computer connected to the network may write the program in the storage device 104, and the program stored in the storage device 104 may be loaded into the RAM 102 and executed in the CPU 101. The program referred to here includes not only a program directly executable by the CPU 101 but also a source program, a compressed program, an encrypted program and the like.

The operation unit 105 is an input device such as a keyboard, a mouse or a touch panel. A user can provide a predetermined instruction to the information processing apparatus 100 by operating the operation unit 105. The display device 106 is a display device such as a liquid crystal display device and displays a GUI (Graphical User Interface) or the like for receiving an instruction from the user. The input-output I/F 107 is connected to the network.

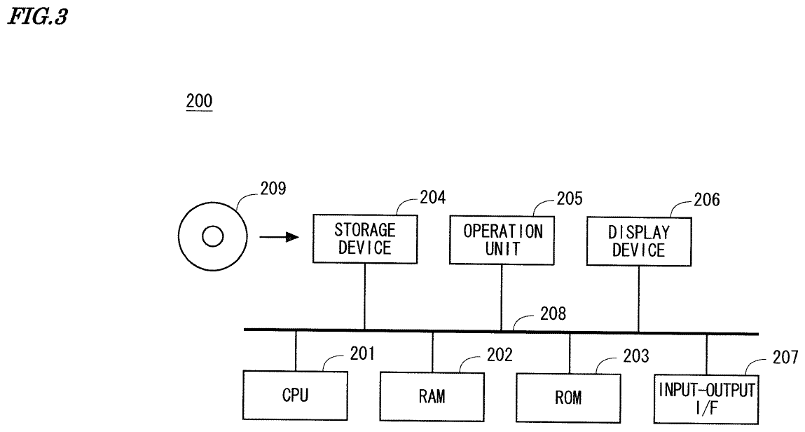

£ FIG. 3 is a diagram showing one example of the configuration of the training device. With reference to FIG. 3, the training device 200 includes a CPU 201, a RAM 202, a ROM 203, a storage device 204, an operation unit 205, a display device 206 and an input-output I/F 207. The CPU 201, the RAM 202, the ROM 203, the storage device 204, the operation unit 205, the display device 206 and the input-output I/F 207 are connected to a bus 208.

The RAM 202 is used as a work area for the CPU 201. A system program is stored in the ROM 203. The storage device 204 includes a storage medium such as a hard disc or a semiconductor memory and stores a program. The program may be stored in the ROM 203 or another external storage device. A CD-ROM 209 is attachable to and detachable from the storage device 204.

The operation unit 205 is an input device such as a keyboard, a mouse or a touch panel. The input-output I/F 207 is connected to the network.

### 3. Functional Configuration of Substrate Processing System

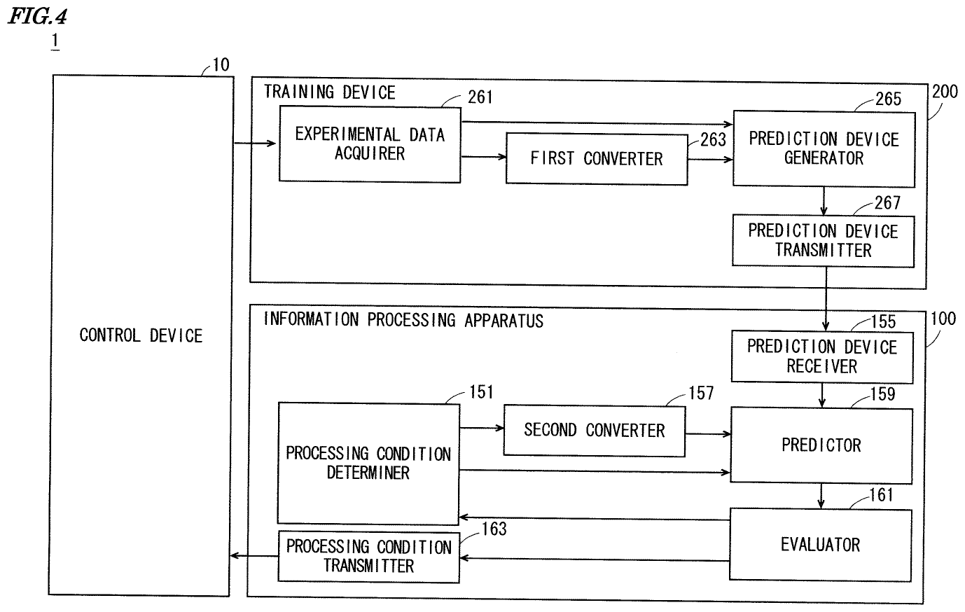

FIG. 4 is a diagram showing one example of the functional configuration of the substrate processing system in one embodiment of the present invention. With reference to FIG. 4, the control device 10 included in the substrate processing apparatus 300 controls the substrate processing unit WU to process the substrate W according to processing conditions. The processing conditions are the conditions for processing the substrate W in a predetermined processing period of time. The processing period of time is the period of time defined for a substrate process. In the present embodiment, the processing period of time is the period of time during which the nozzle 311 discharges the etching liquid to the substrate W.

The processing conditions include a temperature of the etching liquid, a concentration of the etching liquid, a flow rate of the etching liquid, the number of rotations of the substrate W, and the relative positions of the nozzle 311 and the substrate W with respect to each other. The processing conditions include a variable condition that varies over time. In the present embodiment, the variable condition is the relative positions of the nozzle 311 and the substrate W with respect to each other. The relative positions are indicated by a rotation angle of the nozzle motor 303. The processing conditions include a fixed condition that does not vary over time. In the present embodiment, fixed conditions include a temperature of the etching liquid, a concentration of the etching liquid, a flow rate of the etching liquid and the number of rotations of the substrate W.

The training device 200 causes a learning model to learn training data, and generates an inference model for predicting an etching profile based on processing conditions. Hereinafter, an inference model generated by the training device 200 is referred to as a prediction device.

The training device 200 includes an experimental data acquirer 261, a first converter 263, a prediction device generator 265 and a prediction device transmitter 267. The functions included in the training device 200 are implemented by execution by the CPU 201 included in the training device 200 of a training program stored in the RAM 202.

The experimental data acquirer 261 acquires experimental data from the substrate processing apparatus 300. The experimental data includes processing conditions used in a case in which the substrate processing apparatus 300 actually processes the substrate W, and film-thickness characteristics of a film formed on the substrate W before and after the process.

A film-thickness characteristic is indicated by the film thickness of a film formed on the substrate W at each of a plurality of different positions in a radial direction of the substrate W.

A variable condition includes a relative position of the nozzle 311 with respect to the substrate W, with the relative position changing over time. The substrate W rotates about the first rotation axis AX1, and the nozzle 311 rotates about the second rotation axis AX2. Therefore, a change in relative positions of the nozzle 311 and the substrate W with respect to each other is indicated by a change in position of the nozzle 311. The position of the nozzle 311 is defined by a rotation angle of the nozzle motor 303. Further, the angular rotation range of the nozzle motor 303 is limited to a predetermined range. Further, a processing period of time is a predetermined period. In the present embodiment, the processing period of time is 60 seconds.

FIG. 5 is a diagram for explaining a change in relative position of the nozzle with respect to the substrate. With reference to FIG. 5, the change in relative position of the nozzle 311 with respect to the substrate W held by the spin chuck SC is shown. The nozzle 311 moves in the area above the substrate W held by the spin chuck SC. Because the nozzle rotates about the second rotation axis AX2, the trajectory on which the nozzle 311 moves is an arc. The trajectory on which the nozzle 311 moves passes through a substrate center OP, which is the center of the substrate. Therefore, the nozzle 311 moves from the substrate center OP to the entire peripheral portion in the radial direction of the substrate W. Here, in regard to the trajectory on which the nozzle 311 moves, its one end is indicated by a work end portion EP1 located farther inward than the peripheral portion of the substrate W, and the other end is indicated by a work end portion EP2 located farther inward than the peripheral portion of the substrate W. The scan in which the nozzle 311 moves from the work end portion EP1 to the substrate center OP is indicated by an arrow a1, the scan in which the nozzle 311 moves from the substrate center OP to the work end portion EP2 is indicated by an arrow a2, the scan in which the nozzle 311 moves from the work end portion EP2 to the substrate center OP is indicated by an arrow a3, and the scan in which the nozzle 311 moves from the substrate center OP to the work end portion EP1 is indicated by an arrow a4.

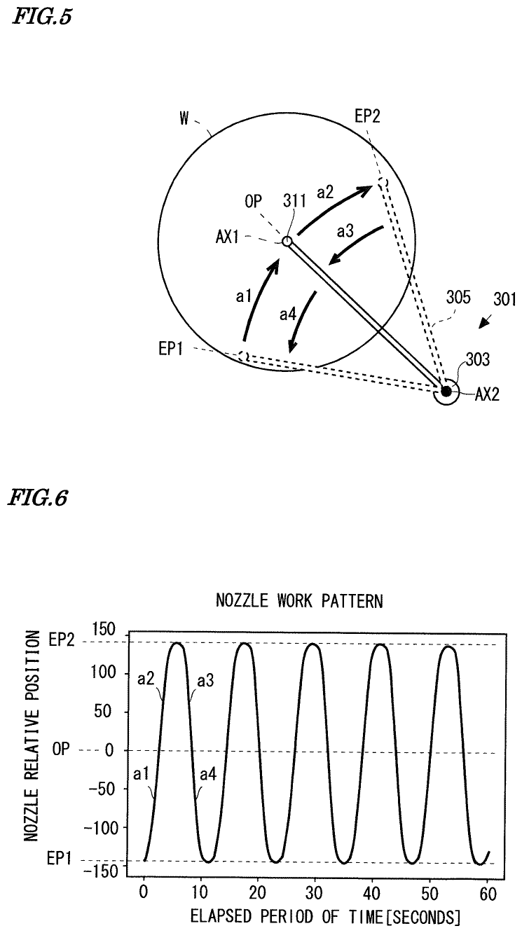

FIG. 6 is a diagram showing one example of the nozzle work pattern. In FIG. 6, the ordinate indicates a relative position of the nozzle 311 with respect to the substrate W, and the abscissa indicates an elapsed period of time (seconds). In the present embodiment, a scanning period from the start to the end of the nozzle work for moving the nozzle 311 with respect to the substrate W is equal to a processing period of time. As described above, because the processing period of time is set to 60 seconds, the nozzle work pattern is represented using the relative positions in the period of 0 to 60 seconds. In regard to the relative position of the nozzle, the position of the substrate center OP is set to 0, a position in the range from the substrate center OP to the work end portion EP1 is indicated by a negative value, and a position in the range from the substrate center OP to the work end portion EP2 is indicated by a positive value. Because the substrate W has the radius of 300 mm, the distances from the substrate center OP to the work end portions EP1, EP2 are set to be equal to or smaller than ±150 mm. Here, the distance from the substrate center OP to the work end portion EP1 is set to −147 mm, and the distance from the substrate center OP to the work end portion EP2 is set to +147 mm. In the nozzle work pattern of FIG. 6, the relative position of the nozzle 311 in a case in which the nozzle 311 is located at the substrate center OP is indicated by 0, the relative position of the nozzle 311 in a case in which the nozzle 311 is located at the work end portion EP1 is indicated by −147 mm, and the relative position of the nozzle 311 in a case in which the nozzle 311 is located at the work end portion EP2 is indicated by 147 mm.

The nozzle work pattern shown in FIG. 6 is shown as the scan in which the nozzle 311 moves back and forth between the work end portion EP1 and the work end portion EP2 five times. In regard to the scan of the first reciprocation in the nozzle work pattern, the same reference numerals as the reference numerals of the arrows a1 to a4 in FIG. 5 are provided to the portions in FIG. 6 corresponding to the scans shown in FIG. 5.

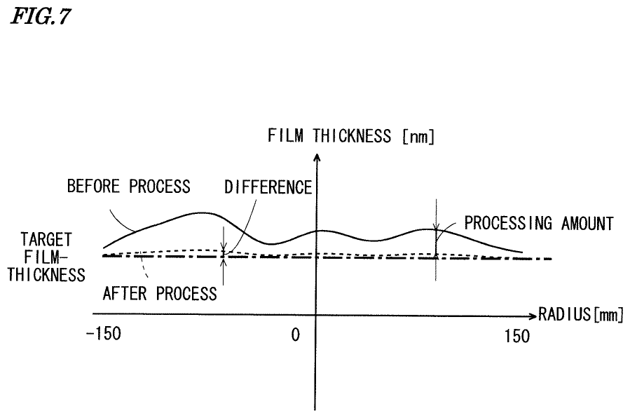

FIG. 7 is a diagram showing one example of the film-thickness characteristic. With reference to FIG. 7, the abscissa indicates a position in the radial direction of the substrate, and the ordinates indicates a film thickness. The origin of the abscissa indicates the center of the substrate. The film thickness of a film formed on the substrate W before being processed by the substrate processing apparatus 300 is indicated by the solid line. The substrate processing apparatus 300 executes a process of applying an etching liquid according to processing conditions, thereby adjusting the film thickness of the film formed on the substrate W. The film thickness of the film formed on the substrate W after the substrate W is processed by the substrate processing apparatus 300 is indicated by the dotted line.

The difference between the film thickness of the film formed on the substrate W before the substrate W is processed by the substrate processing apparatus 300 and the film thickness of the film formed on the substrate W after the substrate W is processed by the substrate processing apparatus 300 is a processing amount (etching amount). The processing amount indicates the film thickness by which the film is reduced in the process of applying the etching liquid by the substrate processing apparatus 300. The distribution in the radial direction of the processing amount is referred to as an etching profile. The etching profile includes the processing amount at each of the plurality of positions in the radial direction of the substrate W.

Further, it is desirable that the film thickness of a film formed by the substrate processing apparatus 300 is uniform over the entire surface of the substrate W. Therefore, a target film-thickness is defined for the process executed by the substrate processing apparatus 300. The target film-thickness is indicated by the one-dot and dash line. A deviation characteristic is the difference between the film thickness of a film formed on the substrate W after the substrate W is processed by the substrate processing apparatus 300 and the target film-thickness. The deviation characteristic includes the difference generated at each of the plurality of positions in the radial direction of the substrate W.

Referring back to FIG. 4, the first converter 263 converts a variable condition included in processing conditions of experimental data received from the experimental data acquirer 261 into low-dimensional compressed data. Here, the variable condition is the relative position of the nozzle 311 with respect to the substrate W, with the relative position changing over time. The first converter 263 outputs the compressed data to the prediction device generator 265.

The compressed data indicates a work amount relating to the nozzle for each of a plurality of movement sections, with the plurality of movement sections being obtained when at least part of a movement range in which the nozzle 311 moves in a scanning period from the start to the end of the nozzle work for moving the nozzle 311 with respect to the substrate W into a number smaller than the number of data sets of the variable condition. A work amount is the period of time during which the nozzle 311 is located in a movement section in regard to each of the plurality of movement sections. Here, the compressed data will be described.

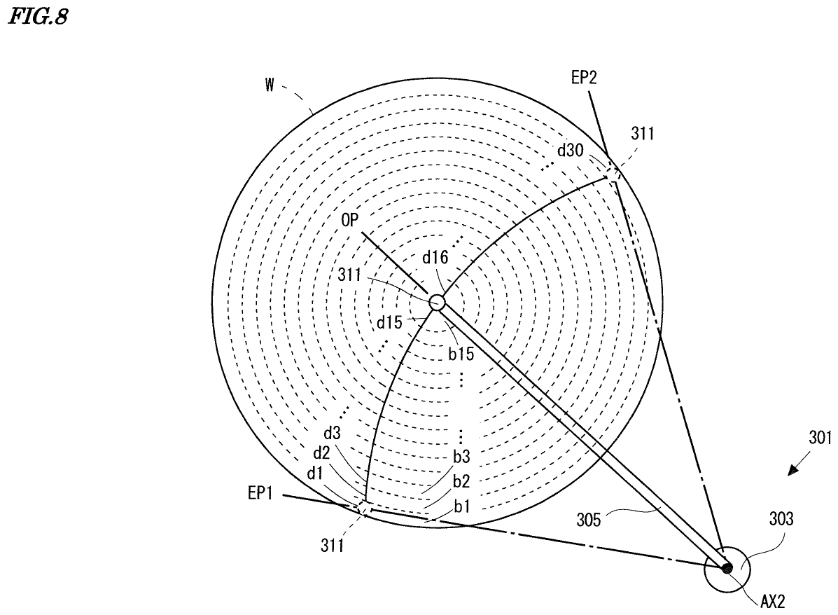

FIG. 8 is a diagram for explaining divided areas. With reference to FIG. 8, the 15divided areas b1 to b15 obtained when the upper surface of the substrate W is divided by a plurality of concentric circles centered at the substrate center OP are shown. The divided area b15 is a circle, and the divided areas b1 to b14 are rings. The lengths of the plurality of divided areas b1 to b14 in the radial direction of the substrate W are the same. The length of each of the division areas b1 to b14 in the radial direction of the substrate is the difference between the radius of the outer periphery and the radius of the inner periphery. The radius of the divided area b15 is equal to the length of each of the plurality of divided areas b1 to b14 in the radial direction of the substrate W. Here, the radius of the divided area b15 is 10 mm, and the difference between the radius of the outer periphery and the radius of the inner periphery of each of the divided areas b1 to b14 is 10 mm. The difference between the radii of the outer and inner peripheries of each of the divided areas b1 to b14 and the radius of the divided area b15 are larger than the inner diameter of the nozzle 311. The length of each of the divided areas b1 to b15 in the radial direction of the substrate and the radius of the divided area b15 are preferably equal to or larger than the inner diameter of the nozzle 311.

Because the nozzle 311 rotates about the second rotation axis AX2, the rotation center is different from the substrate center OP. The movement range in which the nozzle 311 moves is a trajectory that is drawn in a period during which the nozzle 311 moves from the work end portion EP1 to the work end portion EP2 through the substrate center OP and is an arc.

The movement range in which the nozzle 311 moves is the trajectory on which the nozzle 311 moves in a processing period (scanning period) during which the nozzle 311 processes the substrate. The movement range is divided into 30 movement sections d1 to d30 by the divided areas b1 to b15. The movement sections p1 to p15 are the sections that respectively cross the divided areas b1 to b15 of the trajectory on which the nozzle 311 moves between the work end portion EP1 and the substrate center OP. For example, the movement section d1 crosses the divided area b1 in a period during which the nozzle 311 moves on the trajectory between the work end portion EP1 and the substrate center OP. Further, the movement sections p16 to p30 are the sections that respectively cross the divided areas b1 to b15 of the trajectory on which the nozzle 311 moves between the work end portion EP2 and the substrate center OP. For example, the movement section d30 is the section that crosses the divided area b1 in a period during which the nozzle 311 moves between the work end portion EP2 and the substrate center OP. The number of the divided areas b1 to b15 is not limited to 15, and can be set to any value. In this case, the number of divisions of the moving range, in other words, the number of movement sections changes.

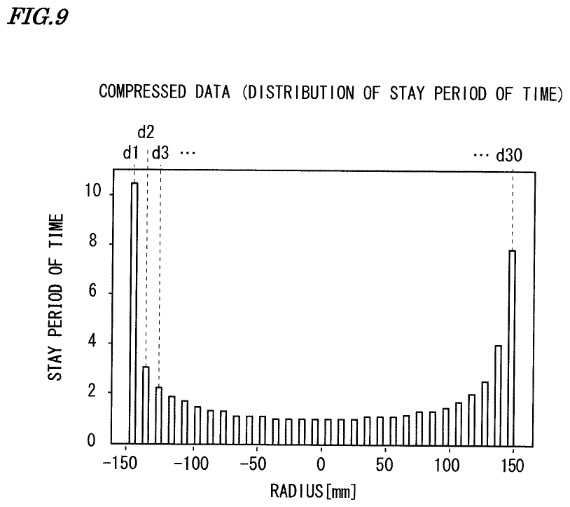

FIG. 9 is a diagram showing one example of compressed data. In FIG. 9, the abscissa indicates a position on the substrate W. The position of the substrate center OP is indicated by 0 mm, one end portion in the radial direction of the substrate W is indicated by −150 mm, and the other end portion in the radial direction of the substrate W is indicated by 150 mm. The movement sections d1 to d30 are allocated between −150 mm and +150 mm of the ordinate.

The ordinate represents a stay period of time during which the nozzle 311 stays in each of the movement sections d1 to d30. Here, the stay period of time during which the nozzle 311 stays in each of the movement sections d1 to d30 in a case in which the nozzle 311 moves according to the work pattern shown in FIG. 6 is shown. The stay period of time is the total period of time during which the nozzle 311 is located in each of the plurality of movement sections d1 to d30. For example, in a case in which the nozzle 311 moves according to the nozzle work pattern shown in FIG. 6, the nozzle 311 crosses the movement section d2 ten times. The stay period of time for the movement section d2 is the total period of time during which the nozzle crosses the movement section d2.

As described above, the movement range of the nozzle 311 is divided into the plurality of movement sections d1 to d30. Therefore, the stay period of time of the nozzle 311 in each of the plurality of divided areas b1 to b15 is calculated for each of the plurality of divided areas b1 to b15 including the information in regard to the position in the radial position of the substrate W. Therefore, the stay period of time during which the nozzle 311 stays in each of the plurality of divided areas b1 to b15 is the information including the position in the radial direction of the substrate W. Further, the lengths, in the radial direction of the substrate W, of the portions of the plurality of divided areas b1 to b15, which the nozzle 311 crosses are the same. Therefore, the stay period of time during which the nozzle 311 stays in each of the plurality of divided areas b1 to b15 can be set as a period of time without deviations among the positions in the radial direction of the substrate W in regard to variations in relative position of the nozzle 311 with respect to the substrate.

Further, in the present embodiment, because the upper surface of the substrate W is divided into the 15 divided areas b1 to b15, the number of compressed data sets is 30. The larger the length of each of the divided areas b1 to b15 in the radial direction of the substrate, the smaller the number of compressed data sets. The length of each of the divided areas b1 to b15 in the radial direction of the substrate is equal to or larger than the inner diameter of the nozzle 311. Therefore, the maximum value of the number of compressed data sets is defined based on the inner diameter of the nozzle 311.

Referring back to FIG. 4, the prediction device generator 265 receives the compressed data obtained as a result of conversion of the variable condition from the first converter 263 and receives the experimental data from the experimental data acquirer 261. The prediction device generator 265 generates a prediction device by causing the neural network to execute supervised learning. The neural network may be a convolutional neural network.

Specifically, training data includes input data and ground truth data. The input data includes the compressed data obtained when the variable condition is converted by the first converter 263 and fixed conditions other than the variable condition of the processing conditions included in the experimental data. The ground truth data includes an etching profile. The etching profile is the difference between the film-thickness characteristic of a film that is obtained before the process and included in the experimental data, and the film-thickness characteristic of the film that is obtained after the process and included in the experimental data. The etching profile included in the ground truth data is one example of a first processing amount. The prediction device generator 265 inputs the input data to the neural network and determines parameters of the neural network such that the output of the neural network is equal to the ground truth data. The prediction device generator 265 generates, as a prediction device, a neural network in which the parameters set in the trained neural network are incorporated. The prediction device is an inference program in which the parameters set in the trained neural network are incorporated. The prediction device generator 265 transmits the prediction device to the information processing apparatus 100.

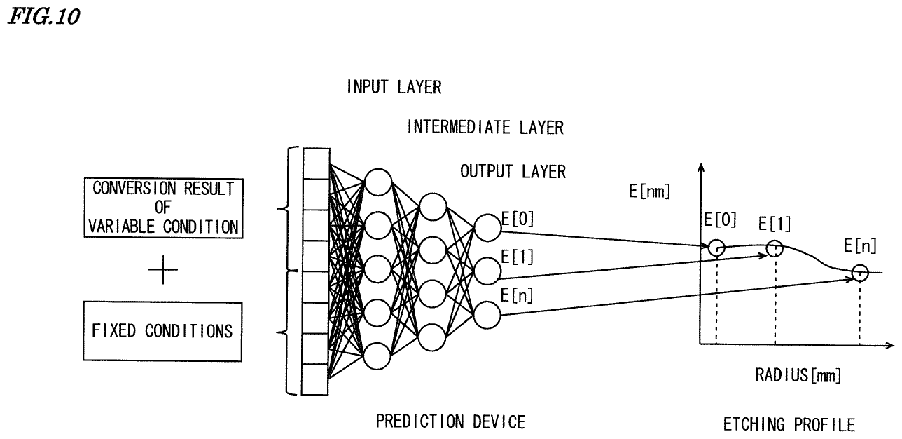

FIG. 10 is a diagram for explaining a prediction device. With reference to FIG. 10, the prediction device includes an input layer, an intermediate layer and an output layer, and each layer includes a plurality of nodes indicated by the circles. While one intermediate layer is shown in the diagram, the number of intermediate layers may be larger than one. Although five nodes are shown in the input layer, four nodes are shown in the intermediate layer, and three nodes are shown in the output layer, the numbers of nodes are not limited to these. The output of an upper node is connected to the input of a lower node. A parameter includes a coefficient for weighting the output of an upper node. Further, the number of intermediate layers is equal to or larger than 1 and not limited.

When the compressed data obtained when a variable condition is converted into a low-dimensional data set and fixed conditions are input to a prediction device, an etching profile is output. The etching profile that is output by this prediction device is one example of a second processing amount. The etching profile is represented by the difference E[n] between the film thickness obtained before a process and the film thickness obtained after the process at each of a plurality of positions P[n] (n is an integer equal to or larger than 1) in the radial direction of the substrate W. Although the number of output nodes of the prediction device is 3 in the diagram, the number of output nodes is actually n.

Referring back to FIG. 4, the information processing apparatus 100 includes a processing condition determiner 151, a prediction device receiver 155, a second converter 157, a predictor 159, an evaluator 161 and a processing condition transmitter 163. The functions included in the information processing apparatus 100 are implemented by execution, by the CPU 101 included in the information processing apparatus 100, of a processing condition determining program stored in the RAM 102.

The prediction device receiver 155 receives a prediction device transmitted from the training device 200 and outputs the received prediction device to the predictor 159.

The processing condition determiner 151 determines processing conditions for the substrate W to be processed by the substrate processing apparatus 300. The processing condition determiner 151 outputs a variable condition included in the processing conditions to the second converter 157, and outputs fixed conditions included in the processing conditions to the predictor 159. Using design of experiments, pairwise testing or Bayesian inference, the processing condition determiner 151 selects one of a plurality of variable conditions that are prepared in advance and determines processing conditions including the selected variable condition and fixed conditions as processing conditions for prediction to be made by the predictor 159. As the plurality of variable conditions prepared in advance, a plurality of variable conditions generated for generation of a compression device by the training device 200 are preferably used.

The second converter 157 has the similar function to that of the first converter 263 of the above-mentioned training device 200. The second converter 157 compresses a variable condition received from the processing condition determiner 151 into compressed data. The second converter 157 outputs the converted compressed data to the predictor 159.

By using the prediction device, the predictor 159 predicts an etching profile based on the compressed data and fixed conditions. Specifically, the predictor 159 inputs the compressed data received from the second converter 157 and the fixed conditions received from the processing condition determiner 151 to the prediction device, and outputs the etching profile output by the prediction device to the evaluator 161.

The evaluator 161 evaluates the etching profile received from the predictor 159 and outputs the evaluation result to the processing condition determiner 151. In detail, the evaluator 161 acquires the film-thickness characteristic obtained before the substrate W to be processed by the substrate processing apparatus 300 is processed. The evaluator 161 calculates the film-thickness characteristic predicted to be obtained after the etching process based on the etching profile received from the predictor 159 and the film-thickness characteristic before the substrate W is processed, and compares the calculated film-thickness characteristic with a target film-thickness characteristic. When the comparison result satisfies an evaluation criterion, the processing conditions determined by the processing condition determiner 151 are output to the processing condition transmitter 163. For example, the evaluator 161 calculates a deviation characteristic and determines whether the deviation characteristic satisfies the evaluation criterion. The deviation characteristic is the difference between the film-thickness characteristic of the substrate W obtained after the etching process and the target film-thickness characteristic. The evaluation criterion can be arbitrarily defined. For example, the evaluation criterion may be that the maximum value of difference in regard to the deviation characteristic is equal to or smaller than a threshold value, or that the average of differences is equal to or smaller than the threshold value.

The processing condition transmitter 163 transmits the processing conditions determined by the processing condition determiner 151 to the substrate processing apparatus 300. The substrate processing apparatus 300 processes the substrate W according to the processing conditions.

In a case in which the evaluation result does not satisfy the evaluation criterion, the evaluator 161 outputs the evaluation result to the processing condition determiner 151. The evaluation result includes the difference between a film-thickness characteristic predicted to be obtained after the etching process and a target film-thickness characteristic.

In response to receiving the evaluation result from the evaluator 161, the processing condition determiner 151 determines new processing conditions for prediction to be made by the predictor 159. Using design of experiments, pairwise testing or Bayesian inference, the processing condition determiner 151 selects one of a plurality of variable conditions that are prepared in advance and determines processing conditions including a selected variable condition and the fixed conditions as new processing conditions for prediction to be made by the predictor 159.

The processing condition determiner 151 may search for processing conditions using Bayesian inference. In a case in which a plurality of evaluation results are output by the evaluator 161, a plurality of sets each of which includes processing conditions and an evaluation result are obtained. Based on the likelihood of the etching profile for each of the plurality of sets, the processing conditions that cause the film thickness to be uniform or the processing conditions that cause the difference between a film-thickness characteristic predicted to be obtained after an etching process and a target film-thickness characteristic to be minimized are searched.

Specifically, the processing condition determiner 151 searches for the processing conditions that cause an objective function to be minimized. The objective function is a function representing the uniformity of film thickness of a film or a function representing the coincidence between the film-thickness characteristic of a film and a target film-thickness characteristic. For example, the objective function is a function that represents the difference between the film-thickness characteristic predicted to be obtained after the etching process and a target film-thickness characteristic using a parameter. The parameter here is the compressed data obtained by conversion of a corresponding variable condition by the second converter 157. The corresponding variable condition is a variable condition before the compressed data used by the prediction device to predict the etching profile is converted. The processing condition determiner 151 selects a variable condition corresponding to compressed data which is a parameter determined by search among a plurality of variable conditions, and determines new processing conditions including the selected variable condition and fixed conditions.

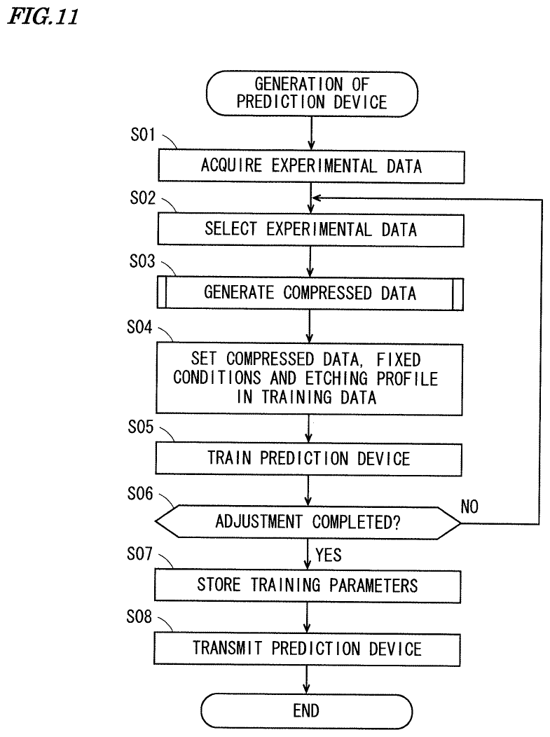

FIG. 11 is a flowchart showing one example of a flow of a prediction device generation process. The prediction device generation process is a process executed by the CPU 201 included in the training device 200 when the CPU 201 executes a prediction device generation program stored in the RAM 202. The prediction device generation program is part of the training program.

With reference to FIG. 11, the CPU 201 included in the training device 200 acquires experimental data. The CPU 201 controls the input-output I/F 107 to acquire the experimental data from the substrate processing apparatus 300 (step S01). The experimental data may be acquired when the experimental data recorded in a recording medium such as the CD-ROM 209 is read by the storage device 104. A plurality of experimental data sets are acquired here. The experimental data sets include processing conditions and the film-thickness characteristics of a film formed on the substrate W obtained before and after a process. The film-thickness characteristics are represented by the film thicknesses of the film formed on the substrate W at each of a plurality of different positions in the radial direction of the substrate W.

In the next step S02, an experimental data set to be processed is selected, and the process proceeds to the step S03. In the step S03, a compressed data generation process is executed, and the process proceeds to the step S04. Although being described below in detail, the compressed data generation process is a process of converting a variable condition included in the experimental data into compressed data.

In the step S04, the compressed data, fixed conditions included in the experimental data sets, and an etching profile are set in training data. The etching profile is the difference between the film-thickness characteristic of a film that is obtained before a process and included in the experimental data sets, and the film-thickness characteristic of the film that is obtained after the process and included in the experimental data sets. The training data includes input data and ground truth data. The compressed data obtained by conversion in the step S03 and the fixed conditions included in the experimental data sets are set as input data. The etching profile is set as ground truth data.

In the next step S05, the CPU 201 causes a prediction device to execute machine learning, and the process proceeds to the step S06. The input data is input to the prediction device which is a neural network, and parameters are determined such that the output of the prediction device is equal to the ground truth data. Thus, parameters of the prediction device are adjusted. The prediction device is a neural network having the parameters determined by machine learning using the training data. The neural network may be a convolutional neural network.

In the step S06, whether adjustment has completed is determined. Training data used for evaluation of the prediction device is prepared in advance, and the performance of the prediction device is evaluated using the training data for evaluation. In a case in which the evaluation result satisfies a predetermined evaluation criterion, it is determined that adjustment is completed. If the evaluation result does not satisfy the evaluation criterion (NO in the step S06), the process returns to the step S02. If the evaluation result satisfies the evaluation criterion (YES in the step S06), the process proceeds to the step S07.

In a case in which the process returns to the step S02, an experimental data set that has not been selected as being subjected to a process is selected from among the experimental data sets acquired in the step S01. In the loop of the step S02 to the step S06, the CPU 201 causes the prediction device to execute machine learning using a plurality of training data sets. Thus, parameters of the prediction device which is a neural network are adjusted to appropriate values. In the step S08, the prediction device is transmitted, and the process ends. The CPU 201 controls the input-output I/F 107 and transmits the prediction device to the information processing apparatus 100.

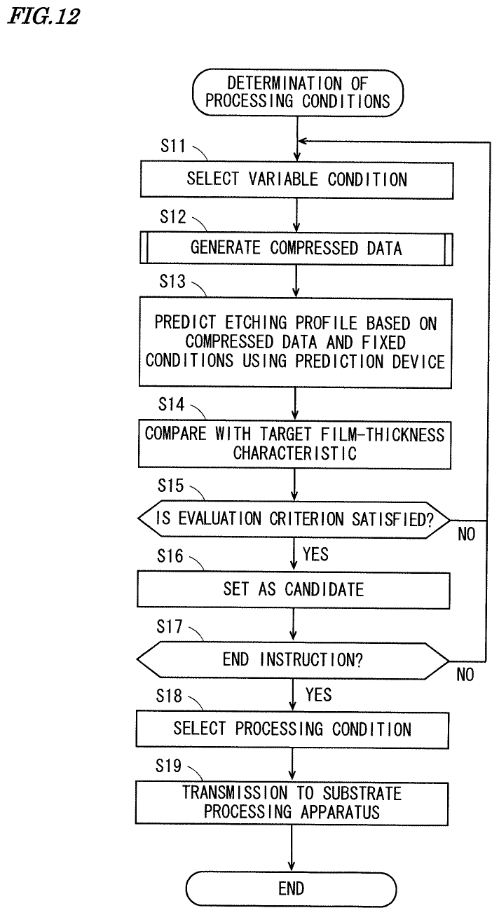

FIG. 12 is a flowchart showing one example of a flow of a processing condition determining process. The processing condition determining process is a process executed by the CPU 101 when the CPU 101 included in the information processing apparatus 100 executes the processing condition determining program stored in the RAM 102.

With reference to FIG. 12, the CPU 101 included in the information processing apparatus 100 selects one of a plurality of variable conditions that are prepared in advance (step S11), and the process proceeds to the step S12. The plurality of variable conditions are a plurality of variable conditions generated for generation of a compression device by the training device 200. Using design of experiments method, pairwise testing, Bayesian inference or the like, one of the plurality of variable conditions prepared in advance is selected.

In the step S12, a compressed data generation process is executed, and the process returns to the step S13. Details of the compressed data generation process will be described below.

In the step S13, an etching profile is predicted based on the compressed data and fixed conditions using the prediction device, and the process proceeds to the step S14. The compressed data generated in the step S12 and the fixed conditions are input to the prediction device, and the etching profile output by the prediction device is acquired. In the step S14, a film-thickness characteristic obtained after a process is compared with a target film-thickness characteristic. Based on a film-thickness characteristic obtained before the process for the substrate W to be processed by the substrate processing apparatus 300 and the etching profile predicted in the step S13, a film-thickness characteristic obtained after the substrate W is processed is calculated. Then, the film-thickness characteristic obtained after the process is compared with the target film-thickness characteristic. Here, the difference between the film-thickness characteristic obtained after the substrate W is processed and the target film-thickness characteristic is calculated.

In the step S15, whether the comparison result satisfies an evaluation criterion is determined. If the comparison result satisfies the evaluation criterion (YES in the step S15), the process proceeds to the step S16. If not, the process returns to the step S11. For example, in a case in which the maximum value for the difference is equal to or smaller than a threshold value, it is determined that the evaluation criterion is satisfied. Further, in a case in which the average value for the difference is equal to or smaller than the threshold value, it is determined that the evaluation criterion is satisfied.

In the step S16, processing conditions including a variable condition selected immediately before in the step S11 is set as candidates of a processing condition for driving the substrate processing apparatus 300, and the process proceeds to the step S17. In the step S17, whether an instruction for ending a search has been accepted is determined. If an end instruction provided by the user who operates the information processing apparatus 100 is accepted, the process proceeds to the step S18. If not, the process returns to the step S11. Instead of the end instruction input by the user, whether a predetermined number of processing conditions have been set as candidates may be determined.

In the step S18, one of the one or more processing conditions set as the candidates is selected, and the process proceeds to the step S19. One of the one or more processing conditions set as the candidates may be selected by the user who operates the information processing apparatus 100. This widens the range of selection for the user. Further, a variable condition according to which the nozzle work can be performed most simply may be automatically selected from among variable conditions included in a plurality of processing conditions. The variable condition according to which the nozzle work is performed most simply can be a variable condition according to which the nozzle work is performed with the smallest number of positions at which the velocity is changed, for example. Thus, a plurality of variable conditions can be presented in regard to a processing result for the complicated nozzle work for processing the substrate W. When a variable condition according to which the nozzle is easily controlled is selected from among a plurality of variable conditions, the control of the substrate processing apparatus 300 is facilitated.

In the step S19, the processing conditions including the variable condition determined in the step S18 are transmitted to the substrate processing apparatus 300, and the process ends. The CPU 101 controls the input-output I/F 107 and transmits the processing conditions to the substrate processing apparatus 300. In a case in which receiving the processing conditions from the information processing apparatus 100, the substrate processing apparatus 300 processes the substrate W according to the processing conditions.

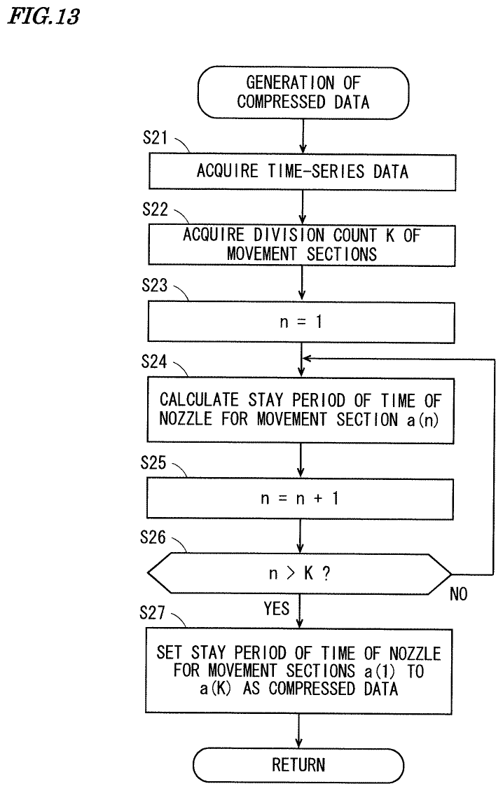

FIG. 13 is a flowchart showing one example of a flow of the compressed data generation process. The compressed data generation process is a process executed in the step S03 of FIG. 11 or the step S12 of FIG. 12. In the step S21, time-series data representing the work of the nozzle 311 performed in a chronological order is acquired. In the step S22, in the time-series data, a division count K (K is an integer equal to or larger than 2) for setting a plurality of movement sections is acquired. In the present embodiment, the division count K is set in advance. The division count K may be input by a user through the operation unit or the like. In the example of FIG. 6, the division count K is set to 30.

In the step S23, a variable n is set to 1. In the step S24, the stay period of time during which the nozzle 311 stays in the movement section d(n) is calculated. The movement section d(n) indicates the n-th movement section out of the movement sections d1 to d30. When the stay period of time during which the nozzle 311 stays in the movement section d(n) is calculated, 1 is added to the variable n in the step S25. At this time, in the step S26, whether the variable n is larger than the division count K is determined. In a case in which the variable n is equal to or smaller than the division count K, the process returns to the step S24. In a case in which the variable n is larger than the division count K, the calculated stay period of time during which the nozzle 311 stays in the movement sections d(1) to d(K) is set in the compressed data in the step S27. By repetition of the steps S24 to S26, the stay period of time during which the nozzle 311 stays in each of the movement sections d(1) to d(K) is calculated.

### 4. Specific Examples

In the present embodiment, a variable condition is the time-series data that is sampled at sampling intervals of 0.01 seconds with a processing period of time for the nozzle work being 60 seconds. The variable condition includes 6001 values. Therefore, the variable condition can express a complicated nozzle work. In particular, the nozzle work having the relatively large number of positions at which the moving velocity of the nozzle is changed can be accurately represented using a variable condition. In contrast, because the number of variable conditions is large, in a case in which machine learning is executed using the time-series data of the variable conditions, overfitting may occur.

The first converter 263 in the present embodiment converts the variable condition into compressed data. The compressed data is the stay period of time during which the nozzle 311 stays in each of a plurality of movement sections obtained when the movement section of the nozzle 311 is divided by a division count 30. The inventor of the present invention has discovered through an experiment that, even in a case in which the variable condition including 6001 values and indicating a complicated nozzle work is converted into compressed data, a desired result is obtained as an etching profile predicted by a prediction device.

Therefore, because the number of data sets to be input to the prediction device can be reduced, the configuration of the prediction device can be simplified, and a neural network can be easily trained. Further, parameters of the neural network can be adjusted to appropriate values, and the accuracy of the prediction device can be improved.

Further, because the variable condition the number of dimensions of which is 6001 is converted into the compressed data the number of dimensions of which is 30, a plurality of variable conditions having the same compressed data among a plurality of variable conditions may be present. In this case, the etching profiles predicted by the prediction device based on the plurality of variable conditions having the same compressed data are the same. In the present embodiment, when searching for processing conditions, the processing condition determiner 151 searches for processing conditions respectively corresponding to different etching profiles. Therefore, the processing conditions corresponding to the plurality of different etching profiles are selected. Therefore, the processing condition determiner 151 can efficiently search for processing conditions with which the target etching profile is predicted to be obtained from among a plurality of processing conditions.

While being set to 0.01 seconds by way of example, the sampling interval is not limited to this. The sampling interval may be longer or shorter than this. For example, the sampling interval may be 0.1 seconds or 0.005 seconds.

### 5. Other Embodiments

(1) In the above-mentioned embodiment, the training device 200 generates a prediction device based on training data. The training device 200 may additionally train a prediction device. After a prediction device is generated, the training device 200 acquires the film-thickness characteristics of a film obtained before and after the substrate W is processed by the substrate processing apparatus 300, and processing conditions. Then, the training device 200 generates training data based on the film-thickness characteristics of the film obtained before and after the process, and the processing conditions, and causes the prediction device to execute machine learning, thereby additionally training the prediction device. While not changing change the configuration of a neural network constituting the prediction device, the additional training adjusts parameters.

Because the prediction device executes machine learning using the information obtained as a result of the process actually executed on the substrate W by the substrate processing apparatus 300, the accuracy of the prediction device can be improved. Further, the number of training data sets used for generating the prediction device can be reduced as much as possible.

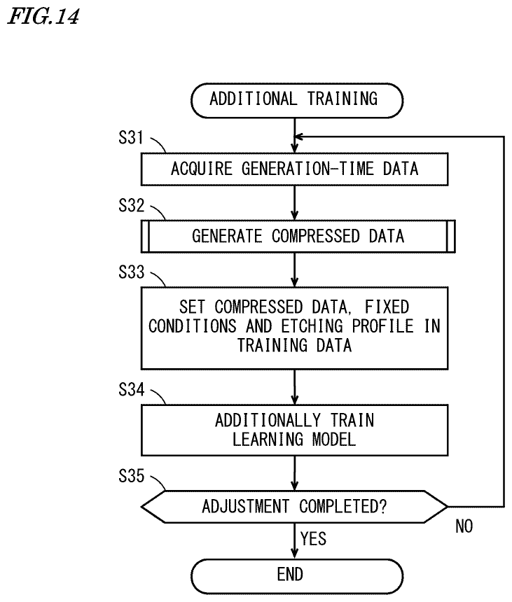

FIG. 14 is a flowchart showing one example of a flow of an additional training process. The additional training process is a process executed by the CPU 201 included in the training device 200 when the CPU 201 executes an additional training program stored in the RAM 202. The additional training program is part of the training program.

With reference to FIG. 14, the CPU 201 included in the training device 200 acquires generation-time data (step S31), and the process proceeds to the step S32. The generation-time data includes processing conditions for a process executed on the substrate W by the substrate processing apparatus 300 and film-thickness characteristics of a film obtained before and after the process. The CPU 201 controls the input-output I/F 107 and acquires the generation-time data from the substrate processing apparatus 300. The generation-time data may be acquired when experimental data recorded in a recording medium such as the CD-ROM 209 is read by the storage device 104.

In the step S32, the compressed data generation process shown in FIG. 13 is executed, and the process proceeds to the step S33. A variable condition is converted into compressed data by execution of the compressed data generation process. In the step S33, the compressed data, fixed conditions included in the processing conditions of the generation-time data and an etching profile are set. The etching profile is the difference between the film-thickness characteristic of a film that is obtained before a process and included in the generation-time data and the film-thickness characteristic of the film that is obtained after the process and included in the generation-time data. The compressed data generated by the first converter 263 and the fixed conditions included in the processing conditions are set in input data. The etching profile is set as ground truth data.

In the next step S34, the CPU 201 additionally trains the prediction device, and the process proceeds to the step S35. The input data is input to the prediction device which is a neural network, and parameters are determined such that the output of the prediction device is equal to the ground truth data. Thus, parameters of the prediction device are further adjusted.

In the step S35, whether adjustment has completed is determined. The performance of the prediction device is evaluated using training data for evaluation. In a case in which the evaluation result satisfies a predetermined additional training evaluation criterion, it is determined that adjustment is completed. The additional training evaluation criterion is a criterion higher than an evaluation criterion used in a case in which a prediction device is generated. If the evaluation result does not satisfy the additional training evaluation criterion (NO in the step S35), the process returns to the step S31. If the evaluation result satisfies the additional training evaluation criterion (YES in the step S35), the process ends.
(2) The training device 200 may generate a distillation model obtained when a new learning model executes machine training, by using distillation data that includes processing conditions determined by the information processing apparatus 100 and an etching profile predicted by a prediction device based on the processing conditions. This facilitates preparation of data for training a new learning model.
(3) In the present embodiment, in the training data used for generation of a prediction device, input data includes the compressed data obtained when a variable condition is converted and fixed conditions. The present invention is not limited to this. The input data may include only compressed data obtained when a variable condition is converted, and does not have to include fixed conditions.
(4) While the first converter 263 and the second converter 157 convert the time-series data relating to the movement of the nozzle 311 into compressed data representing a stay period of time during which the nozzle 311 stays in each of the plurality of movement sections by way of example in the present embodiment, the present invention is not limited to this. While the supply amount of the processing liquid is constant by way of example in the above-mentioned embodiment, for example, the supply amount of the processing liquid may vary over time. In this case, the variable condition includes the supply amount of the processing liquid that varies over time. In this case, the compressed data is the supply amount of the processing liquid in each of the plurality of movement sections.

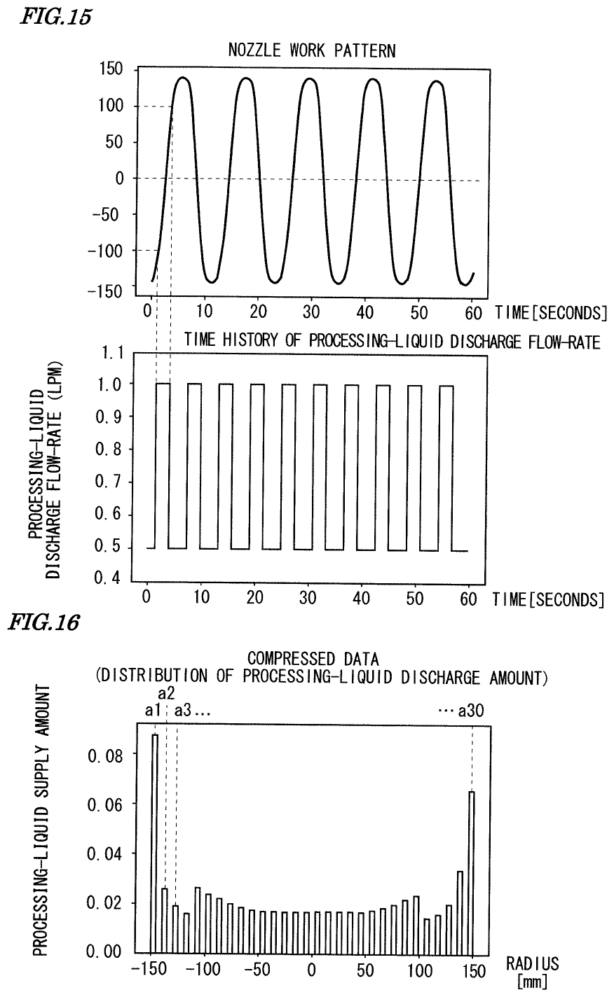

FIG. 15 is a diagram showing one example of a processing liquid supply amount that changes over time. In the upper field of FIG. 15, the time-series data similar to the nozzle work pattern shown in FIG. 6 is shown. In the lower field of FIG. 15, one example of a change in amount of the processing liquid to be discharged from the nozzle 311 (time history of processing-liquid discharge flow-rate) is shown. In the graph shown in the lower field of FIG. 15, the abscissa indicates the time, and the ordinate indicates the flow rate of the processing liquid to be discharged from the nozzle 311. The supply amount of the processing liquid in each of the plurality of movement sections d1 to d30 is calculated based on the relative position of the nozzle that varies over time with respect to the substrate and the flow rate of the processing liquid, with the flow rate varying over time. Specifically, the supply amount of the processing liquid in each of the plurality of movement sections is calculated based on the stay period of time during which the nozzle is located in the movement section and the flow rate of the processing liquid to be supplied from the nozzle 311.

FIG. 16 is a diagram showing another example of compressed data. In FIG. 16, the abscissa indicates a position on the substrate W. The substrate center OP is indicated by 0 mm, one end portion of the substrate in the radial direction is indicated by −150 mm, and the other end portion of the substrate in the radial direction is indicated by 150 mm. The movement sections d1 to d30 are allocated between −150 mm and +150 mm of the ordinate.

The abscissa indicates the supply amount of the processing liquid in each of the movement sections d1 to d30. Here, the supply amount of the processing liquid in each of the movement sections d1 to d30 in a case in which the nozzle 311 moves according to the work pattern shown in FIG. 6 is shown. The accumulated total of the processing liquid to be supplied from the nozzle 311 in the period during which the nozzle 311 is located in each of the movement sections d1 to d30 is calculated as a supply amount. In this case, because the time-series data representing the work of the nozzle 311 is converted into compressed data in consideration of the supply amount of the processing liquid to be supplied to the substrate W, it is possible to generate a more accurate prediction device.
(5) While the information processing apparatus 100 and the training device 200 are separated from the substrate processing apparatus 300 by way of example, the present invention is not limited to this. The information processing apparatus 100 may be incorporated in the substrate processing apparatus 300. Further, the information processing apparatus 100 and the training device 200 may be incorporated in the substrate processing apparatus 300. While being separate apparatuses, the information processing apparatus 100 and the training device 200 may be configured as an integrated apparatus.
(6) While being set to have equal lengths in the radial direction of the substrate in the above-mentioned embodiment, the plurality of movement sections d1 to d3 are respectively set to have different lengths. For example, the movement range may be divided such that the trajectory on which the nozzle 311 moves is equally divided. For example, in a case in which an angle formed by the work end portion EP1 and the work end portion with the second rotation axis AX2 as a center is 60 degrees, the angle of each of the plurality of movement sections d1 to d30 with the second rotation axis AX2 as a center is 2 degrees. In this manner, the plurality of movement sections d1 to d30 can be indicated by the rotation angle of the nozzle motor 303.

### 6. Effects of Embodiments

The training device 200 in the present embodiment drives the substrate processing apparatus 300 according to processing conditions including a variable condition and executes a process for a film formed on the substrate W to then acquire a processing amount indicating the difference between the film thickness of the film formed on the substrate W obtained before a process and the film thickness of the film formed on the substrate W obtained after the process, and causes a neural network to execute machine learning using training data that includes compressed data obtained when the variable condition is converted by the first converter 263 as input data and an etching profile corresponding to the processing conditions as ground truth data, and generates a prediction device that is a learning model for predicting the etching profile. Because the training data includes, as input data, the compressed data obtained when the variable condition that varies over time is converted such that the number of dimensions is reduced, it is possible to reduce the number of dimensions of training data. Therefore, it is possible to generate the training device suitable for machine learning for the process for a film formed on the substrate W, using a condition that varies over time.

Further, because the training device 200 compresses the variable condition into a period of time during which the nozzle 311 stays in each of the plurality of movement sections obtained when the movement range of the nozzle 311 of the substrate processing apparatus 300 is divided, it is possible to easily convert the variable condition into the compressed data.

Further, the processing conditions include a variable condition and fixed conditions that do not vary over time. Therefore, it is possible to manage a process with different fixed conditions, and it is not necessary to generate a plurality of learning models with different fixed conditions.

After generating a prediction device, the training device 200 acquires a processing amount indicating the difference between the film thicknesses of a film formed on the substrate W obtained before and after a process is executed by the substrate processing apparatus 300 on the substrate W according to processing conditions, and causes a learning model to learn additional training data that includes a conversion result obtained when a variable condition is converted by a compression device and the acquired processing amount. Therefore, because the learning model is additionally trained, the performance of the learning model can be improved.

Further, in a case in which a conversion result obtained when a temporary variable condition is converted by a compression device is provided to a learning model, and a processing amount predicted by the learning model satisfies an allowable condition, the training device 200 generates a new learning model using distillation data including the conversion result and the processing amount predicted by the learning model. This facilitates preparation of data for training a new learning model.

Further, the substrate processing apparatus 300 includes the nozzle 311 that supplies a processing liquid to the substrate W and the nozzle moving mechanism 301 that changes the relative positions of the nozzle and the substrate W with respect to each other, and a variable condition is the relative positions of the nozzle 311 changed by the nozzle moving mechanism 301 and the substrate W with respect to each other. A learning model that predicts a processing amount of a film, with the film being processed when the relative positions of the nozzle 311 and the substrate W with respect to each other are changed, and a processing liquid is supplied to the substrate W from the nozzle 311. Therefore, it is possible to generate the learning model that predicts the processing amount in the etching process.

Further, in a case in which compressed data obtained when a temporary variable condition is converted by a compression device generated by the training device 200 is provided to a learning model generated by the training device 200, and an etching profile predicted by the learning model satisfies an allowable condition, the information processing apparatus 100 determines processing conditions including the temporary variable condition as processing conditions for driving the substrate processing apparatus 300. Therefore, because the etching profile is predicted based on the processing conditions, it is not necessary to obtain the influence of the complicated nozzle work on the processing result of an etching process by an experiment or the like. Further, because a plurality of temporary variable conditions are determined for the processing amount satisfying the allowable condition, it is possible to determine a plurality of variable conditions respectively corresponding to a plurality of etching profiles satisfying the allowable condition. Therefore, the plurality of variable conditions can be presented for the processing result of the complicated process for the substrate. When a processing condition according to which the nozzle work is easily controlled is selected from among the plurality of variable conditions, it facilitates the control of the substrate processing apparatus 300.

Further, because determining a plurality of processing conditions for a processing amount satisfying an allowable condition, the information processing apparatus 100 can determine the plurality of processing conditions respectively corresponding to a plurality of etching profiles satisfying the allowable condition. Further, fixed conditions include a temperature of the etching liquid. Therefore, temperatures of a plurality of etching liquids can be presented for a processing result of the complicated process of processing a substrate. Further, a temperature of the etching liquid which is easily applied to the etching process can be selected from among the temperatures of the plurality of etching liquids. Because the temperature of the etching liquid that can be easily applied can be selected, the temperature of the etching liquid used for the etching process can be easily regulated.

### 7. Correspondences Between Constituent Elements in Claims and Parts in Preferred Embodiments

The substrate W is an example of a substrate, the etching liquid is an example of a processing liquid, the substrate processing apparatus 300 is an example of a substrate processing apparatus, the experimental data acquirer 261 is an example of an experimental data acquirer, the first converter 263 is an example of a converter and a first converter, the prediction device is an example of a learning model, and the prediction device generator 265 is an example of a model generator. Further, the information processing apparatus 100 is an example of an information processing apparatus, the second converter 157 is an example of a second converter, the nozzle 311 is one example of a nozzle that supplies a processing liquid to a substrate, the nozzle moving mechanism 301 is an example of a mover, the predictor 159, the evaluator 161 and the processing condition determiner 151 are examples of a processing condition determiner.

### 8. Overview of Embodiments

(Item 1) A training device includes an experimental data acquirer that acquires a first processing amount indicating a difference between a film thickness obtained before a process for a film and a film thickness obtained after the process for the film, after a substrate processing apparatus is driven according to processing conditions including a variable condition indicating a relative position of a nozzle with respect to a substrate and executes the process for the film formed on the substrate, with the relative position varying over time and with the substrate processing apparatus moving the nozzle for supplying a processing liquid to the substrate on which the film is formed and supplying the processing liquid to the substrate, a converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and a model generator that generates a learning model, with the learning model executing machine learning using training data that includes the compressed data and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus.

With the training device according to item 1, the training data includes the compressed data that is obtained when the variable condition indicating the relative position of the nozzle with respect to the substrate, with the relative position varying over time, is converted such that the number of dimensions of the variable condition is reduced, and the processing amount. Therefore, the number of dimensions of the training data can be reduced. As a result, it is possible to provide the training device suitable for machine learning, for a process to be executed on a film formed on the substrate, using a condition that changes over time.
(Item 2) The training device according to item 1, wherein the work amount is a stay period of time during which the nozzle is located in each of the plurality of movement sections.

With the training device according to item 2, because the work amount is the stay period of time during which the nozzle is located in each of the plurality of movement sections, it is possible to easily convert the variable condition into compressed data.
(Item 3) The training device according to item 1 or 2, wherein the variable condition further includes a flow rate of the processing liquid to be discharged to the substrate over time by the substrate processing apparatus, and the work amount is a supply amount of the processing liquid in each of the plurality of movement sections, with the supply amount being calculated based on a stay period of time during which the nozzle is located in the movement section and a flow rate of the processing liquid to be supplied from the nozzle.

With the training device according to item 3, because the supply amount of the processing liquid for each of the plurality of movement sections is considered as a work amount, it is possible to convert the variable condition into compressed data the number of dimensions of which is smaller than the number of dimensions of a plurality of types of variable conditions.
(Item 4) The training device according to any one of items 1 to 3, wherein the plurality of movement sections have equal lengths.

With the training device according to item 4, because the plurality of movement sections are set to have the same length, the compressed data represents the nozzle work in the plurality of movement sections set to have the same length. Therefore, in regard to the entire substrate, it is possible to convert the variable condition into the compressed data without deviations among a plurality of different positions of the substrate in regard to a nozzle work amount with respect to the substrate.
(Item 5) The training device according to item 4, wherein a length of each of the plurality of movement sections is a length in a radial direction of an area on an upper surface of the substrate, which the nozzle crosses when moving in the movement section.

With the training device according to item 5, the length of each of the plurality of movement sections is the length in the radial direction of an area of the substrate, which the nozzle crosses in the period during which the nozzle moves in the movement section. Therefore, it is possible to convert a variable condition into compressed data without deviations among different positions in the radial direction of the substrate in regard to a nozzle work amount with respect to the substrate.
(Item 6) An information processing apparatus that manages a substrate processing apparatus, wherein the substrate processing apparatus processes a film formed on a substrate by supplying a processing liquid to the substrate on which the film is formed, according to processing conditions including a variable condition indicating a relative position of a nozzle with respect to the substrate, with the relative position varying over time, includes a converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and a processing condition determiner that determines processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model is an inference model that has executed machine training using training data, with the training data including compressed data that is obtained when the variable condition included in processing conditions according to which the substrate processing apparatus has executed a process for the film formed on the substrate is converted by the converter, and a first processing amount indicating a difference between a film thickness obtained before the process for the film and a film thickness obtained after the process for the film in regard to the film formed on the substrate that has been processed by the substrate processing apparatus, and the processing condition determiner, in a case in which compressed data obtained when a temporary variable condition is converted by the converter is provided to the learning model and the second processing amount predicted by the learning model satisfies an allowable condition, determines processing conditions including the temporary variable condition as processing conditions for driving the substrate processing apparatus.

With the information processing apparatus according to item 6, in a case in which the compressed data obtained when the temporary variable condition that varies over time is converted is provided to the learning model, and the processing amount predicted by the learning model satisfies the allowable condition, the processing conditions including the temporary variable condition are determined as processing conditions for driving the substrate processing apparatus. Therefore, a plurality of temporary variable conditions can be determined for the processing amount that satisfies the allowable condition. As a result, it is possible to present a plurality of processing conditions for a processing result of a complicated process of processing a film formed on the substrate.
(Item 7) A substrate processing apparatus includes the information processing apparatus according to item 6.

With the substrate processing apparatus according to item 7, it is possible to present a plurality of processing conditions for a processing result of a complicated process of processing a substrate.
(Item 8) A substrate processing system managing a substrate processing apparatus that processes a substrate, includes a training device and an information processing apparatus, wherein the substrate processing apparatus processes a film formed on a substrate by supplying a processing liquid to the substrate on which the film is formed, according to processing conditions including a variable condition indicating a relative position of a nozzle with respect to the substrate, with the relative position varying over time, the training device includes an experimental data acquirer that acquires a first processing amount indicating a difference between a film thickness obtained before a process for a film and a film thickness obtained after the process for the film, after the substrate processing apparatus is driven according to processing conditions and executes the process for the film formed on the substrate, a first converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to a substrate until a time when the substrate processing apparatus ends the nozzle work is divided into a number smaller than a data count of the variable condition, and a model generator that generates a learning model, with the learning model executing machine learning using training data that includes the compressed data obtained when the variable condition is converted by the first converter and the first processing amount corresponding to the processing conditions and predicting a second processing amount that indicates a difference between a film thickness obtained before a process for the film and a film thickness obtained after the process for the film in regard to the film formed on the substrate before being processed by the substrate processing apparatus, the information processing apparatus includes a second converter that is same as the first converter, and a processing condition determiner that determines processing conditions for driving the substrate processing apparatus using the learning model generated by the training device, and the processing condition determiner, in a case in which a conversion result obtained when a temporary variable condition is converted by the second converter is provided to the learning model and a second processing amount predicted by the learning model satisfies an allowable condition, determines processing conditions including the temporary variable condition as processing conditions for driving the substrate processing apparatus.

With the substrate processing system according to item 8, it is suitable for machine training for a process for a film formed on the substrate, using a condition that changes over time, and it is possible to present a plurality of processing conditions for a processing result of a complicated process of processing a film formed on the substrate.
(Item 9) A training method causes a computer to execute the processes of acquiring a first processing amount indicating a difference between a film thickness obtained before a process for a film and a film thickness obtained after the process for the film, after a substrate processing apparatus is driven according to processing conditions including a variable condition indicating a relative position of a nozzle with respect to a substrate and executes the process for the film formed on the substrate, with the relative position varying over time and with the substrate processing apparatus moving the nozzle for supplying a processing liquid to the substrate on which the film is formed and supplying the processing liquid to the substrate, converting the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and generating a learning model, with the learning model executing machine learning using training data that includes the compressed data and the first processing amount corresponding to the processing conditions and predicting a second processing amount that indicates a difference between a film thickness obtained before a process for the film and a film thickness obtained after the process for the film in regard to the film formed on the substrate before being processed by the substrate processing apparatus.

With the training method according to item 9, the training data includes compressed data and a processing amount, with the compressed data being obtained when a variable condition that varies over time is converted such that the number of dimensions of the variable condition is reduced. Therefore, the number of dimensions of the training data can be reduced. As a result, it is possible to provide the training method suitable for machine learning for the process to be executed on a film formed on the substrate, using a condition that changes over time.
(Item 10) A processing condition determining method is executed by a computer that manages a substrate processing apparatus, wherein the substrate processing apparatus processes a film formed on a substrate by supplying a processing liquid to the substrate on which the film is formed, according to processing conditions including a variable condition indicating a relative position of a nozzle with respect to the substrate, with the relative position varying over time, the processing condition determining method includes a process of converting the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and a process of determining processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model is an inference model that has executed machine training using training data, with the training data including compressed data that is obtained when the variable condition included in processing conditions according to which the substrate processing apparatus has executed a process for the film formed on the substrate is converted in the process of converting, and a first processing amount indicating a difference between a film thickness obtained before the process for the film and a film thickness obtained after the process for the film in regard to the film formed on the substrate that has been processed by the substrate processing apparatus, and the process of determining processing conditions, in a case in which compressed data obtained when a temporary variable condition is converted in the process of converting is provided to the learning model and the second processing amount predicted by the learning model satisfies an allowable condition, includes determining processing conditions including the temporary variable condition as processing conditions for driving the substrate processing apparatus.

With the processing condition determining method according to item 10, it is possible to provide a processing condition determining method that enables presentation of a plurality of processing conditions for a result of a complicated process of processing a film formed on the substrate.

1. A training device comprising:
an experimental data acquirer that acquires a first processing amount indicating a difference between a film thickness obtained before a process for a film and a film thickness obtained after the process for the film, after a substrate processing apparatus is driven according to processing conditions including a variable condition indicating a relative position of a nozzle with respect to a substrate and executes the process for the film formed on the substrate, the relative position varying over time, the substrate processing apparatus moving the nozzle for supplying a processing liquid to the substrate on which the film is formed and supplying the processing liquid to the substrate;
a converter that converts the variable condition into compressed data representing a nozzle work amount for each of a plurality of movement sections, the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition; and
a model generator that generates a learning model, the learning model executing machine learning using training data that includes the compressed data and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus.

2. The training device according to claim 1, wherein
the work amount is a stay period of time during which the nozzle is located in each of the plurality of movement sections.

3. The training device according to claim 1, wherein
the variable condition further includes a flow rate of the processing liquid to be discharged to the substrate over time by the substrate processing apparatus, and
the work amount is a supply amount of the processing liquid in each of the plurality of movement sections, with the supply amount being calculated based on a stay period of time during which the nozzle is located in the movement section and a flow rate of the processing liquid to be supplied from the nozzle.

4. The training device according to claim 1, wherein
the plurality of movement sections have equal lengths.

5. The training device according to claim 4, wherein
a length of each of the plurality of movement sections is a length in a radial direction of an area on an upper surface of the substrate, which the nozzle crosses when moving in the movement section.

6. An information processing apparatus that manages a substrate processing apparatus, wherein
the substrate processing apparatus
processes a film formed on a substrate by supplying a processing liquid to the substrate on which the film is formed, according to processing conditions including a variable condition indicating a relative position of a nozzle with respect to the substrate, with the relative position varying over time, and
includes
a converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and
a processing condition determiner that determines processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus,
the learning model is an inference model that has executed machine training using training data, with the training data including compressed data that is obtained when the variable condition included in processing conditions according to which the substrate processing apparatus has executed a process for the film formed on the substrate is converted by the converter, and a first processing amount indicating a difference between a film thickness obtained before the process for the film and a film thickness obtained after the process for the film in regard to the film formed on the substrate that has been processed by the substrate processing apparatus, and
the processing condition determiner, in a case in which compressed data obtained when a temporary variable condition is converted by the converter is provided to the learning model and the second processing amount predicted by the learning model satisfies an allowable condition, determines processing conditions including the temporary variable condition as processing conditions for driving the substrate processing apparatus.

7. A substrate processing apparatus comprising the information processing apparatus according to claim 6.

8. A substrate processing system managing a substrate processing apparatus that processes a substrate, comprising a training device and an information processing apparatus, wherein
the substrate processing apparatus processes a film formed on a substrate by supplying a processing liquid to the substrate on which the film is formed, according to processing conditions including a variable condition indicating a relative position of a nozzle with respect to the substrate, with the relative position varying over time,
the training device includes
an experimental data acquirer that acquires a first processing amount indicating a difference between a film thickness obtained before a process for a film and a film thickness obtained after the process for the film, after the substrate processing apparatus is driven according to processing conditions and executes the process for the film formed on the substrate,
a first converter that converts the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to a substrate until a time when the substrate processing apparatus ends the nozzle work is divided into a number smaller than a data count of the variable condition, and
a model generator that generates a learning model, with the learning model executing machine learning using training data that includes the compressed data obtained when the variable condition is converted by the first converter and the first processing amount corresponding to the processing conditions and predicting a second processing amount that indicates a difference between a film thickness obtained before a process for the film and a film thickness obtained after the process for the film in regard to the film formed on the substrate before being processed by the substrate processing apparatus,
the information processing apparatus includes
a second converter that is same as the first converter, and
a processing condition determiner that determines processing conditions for driving the substrate processing apparatus using the learning model generated by the training device, and
the processing condition determiner, in a case in which a conversion result obtained when a temporary variable condition is converted by the second converter is provided to the learning model and a second processing amount predicted by the learning model satisfies an allowable condition, determines processing conditions including the temporary variable condition as processing conditions for driving the substrate processing apparatus.

9. A training method of causing a computer to execute the processes of:
acquiring a first processing amount indicating a difference between a film thickness obtained before a process for a film and a film thickness obtained after the process for the film, after a substrate processing apparatus is driven according to processing conditions including a variable condition indicating a relative position of a nozzle with respect to a substrate and executes the process for the film formed on the substrate, the relative position varying over time, the substrate processing apparatus moving the nozzle for supplying a processing liquid to the substrate on which the film is formed and supplying the processing liquid to the substrate;
converting the variable condition into compressed data representing a nozzle work amount for each of a plurality of movement sections, the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition; and
generating a learning model, the learning model executing machine learning using training data that includes the compressed data and the first processing amount corresponding to the processing conditions and predicting a second processing amount that indicates a difference between a film thickness obtained before a process for the film and a film thickness obtained after the process for the film in regard to the film formed on the substrate before being processed by the substrate processing apparatus.

10. A processing condition determining method executed by a computer that manages a substrate processing apparatus, wherein
the substrate processing apparatus processes a film formed on a substrate by supplying a processing liquid to the substrate on which the film is formed, according to processing conditions including a variable condition indicating a relative position of a nozzle with respect to the substrate, with the relative position varying over time,
the processing condition determining method includes
a process of converting the variable condition into compressed data representing a nozzle work amount for each of a plurality of movement sections, with the plurality of movement sections being obtained when a movement range in which the nozzle moves during a scanning period from a time when the substrate processing apparatus starts a nozzle work for moving the nozzle with respect to the substrate until a time when the substrate processing apparatus ends the nozzle work is divided into a number smaller than a data count of the variable condition, and
a process of determining processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus,
the learning model is an inference model that has executed machine training using training data, with the training data including compressed data that is obtained when the variable condition included in processing conditions according to which the substrate processing apparatus has executed a process for the film formed on the substrate is converted in the process of converting, and a first processing amount indicating a difference between a film thickness obtained before the process for the film and a film thickness obtained after the process for the film in regard to the film formed on the substrate that has been processed by the substrate processing apparatus, and
the process of determining processing conditions, in a case in which compressed data obtained when a temporary variable condition is converted in the process of converting is provided to the learning model and the second processing amount predicted by the learning model satisfies an allowable condition, includes determining processing conditions including the temporary variable condition as processing conditions for driving the substrate processing apparatus.
